(19) United States
(12) Patent Application Publication
(10) Pub. No.: US 2026/0282899 A1
(43) Pub. Date: Sep. 17, 2026

(54) FIN DESIGN MOLDING STRUCTURE FOR EXPOSED SEMICONDUCTOR PACKAGE FOR CONVECTION HEAT TRANSFER

(71) Applicant: Micron Technology, Inc., Boise, ID (US)

(72) Inventors: See Hiong LEOW, Singapore (SG); Hong Wan NG, Singapore (SG); Chin Hui CHONG, Singapore (SG); Seng Kim YE, Singapore (SG); Kelvin Aik Boo TAN, Singapore (SG); Ling PAN, Singapore (SG)

(21) Appl. No.: 19/448,150

(22) Filed: Jan. 14, 2026

Related U.S. Application Data
(60) Provisional application No. 63/771,728, filed on Mar. 14, 2025.

(51) Int. Cl. H10W 40/22; H10W 40/00; H10W 40/20

(52) U.S. Cl. CPC H10W 40/226; H10W 40/037; H10W 40/242

(57) ABSTRACT

A semiconductor device assembly includes a circuit substrate; a semiconductor die arranged on the circuit substrate; a heat transfer layer arranged on the semiconductor die, the heat transfer layer configured to transfer heat generated by the semiconductor die away from the semiconductor die; and a package casing that partially encapsulates the semiconductor die and the heat transfer layer. The package casing includes a plurality of fin structures and a plurality of channels arranged over the heat transfer layer. The plurality of channels extend from an ambient environment into the package casing to the heat transfer layer to expose portions of the heat transfer layer to the ambient environment. The plurality of channels are configured to receive, from the heat transfer layer, the heat generated by the semiconductor die, and dissipate the heat into the ambient environment, away from the heat transfer layer and the package casing.

### CROSS-REFERENCE TO RELATED APPLICATION

This Patent Application claims priority to U.S. Provisional Patent Application No. 63/771,728, filed on Mar. 14, 2025, entitled “FIN DESIGN MOLDING STRUCTURE FOR EXPOSED SEMICONDUCTOR PACKAGE FOR CONVECTION HEAT TRANSFER,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a fin design molding structure for an exposed semiconductor package for convection heat transfer.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example apparatus that may be manufactured using techniques described herein.

FIG. 3 is a diagram of an example apparatus that may be manufactured using techniques described herein.

FIG. 4 shows a top view of an example apparatus.

FIG. 5 is a graph that depicts warpage profiles for different semiconductor device assemblies.

FIG. 6 is a flowchart of an example method of forming an apparatus having a fin design molding structure for an exposed semiconductor package for convection heat transfer.

### DETAILED DESCRIPTION

Compact electronic devices with higher power and memory densities are increasingly in demand, particularly in devices that support artificial intelligence applications. As the power and memory densities of semiconductor devices grows, so too does the amount of heat generated by the semiconductor devices, which must be managed effectively to maintain device reliability and performance. A crucial aspect of heat management involves the dissipation of heat to an ambient environment through conduction and/or convection. Traditionally, thermal management can involve the attachment of separate heat sinks to a device package, a solution that, while functional, leads to an increase in vertical height or Z-height form factor of the device package, which may be less desirable for compact electronic devices.

Furthermore, the industry seeks solutions that are compatible with existing mold tooling to negate the need for significant investment in new manufacturing processes. The industry may seek cost-effective approaches that enable the use of existing mold tooling and that enable larger die thicknesses, while avoiding the complexities of separate heat sink attachment. Larger die thicknesses may enable dies to include more components for processing and/or memory operations.

Some implementations described herein offer an approach for managing heat dissipation in compact electronic devices with high power and memory densities. For example, a semiconductor device assembly may comprise a circuit substrate with a semiconductor die electrically coupled to it, and a heat transfer layer arranged on a die surface. The semiconductor device assembly may include a package casing with a fin design that partially encapsulates the semiconductor die and the heat transfer layer. The package casing incorporates a plurality of fin structures and channels arranged over the heat transfer layer. The channels, defined by the fin structures, extend from an ambient environment into the package casing directly to the heat transfer layer, thus facilitating direct exposure of portions of the heat transfer layer to the ambient environment. The structure is such that the heat generated by the semiconductor die is received by the channels and dissipated into the ambient environment, away from the heat transfer layer and the package casing.

In some aspects, the heat transfer layer may transfer heat to the channels by convection heat transfer, and the channels may act as convection airflow channels configured to receive and/or circulate convection air currents to remove the heat. Additionally, the heat transfer layer may be a dummy silicon layer or bare silicon layer with a coefficient of thermal expansion (CTE) closely matched to the semiconductor material of the semiconductor die to minimize CTE mismatch issues.

The integration of the fin structures and airflow channels into the package casing's design may enhance heat dissipation efficiency while negating the necessity for additional heat sinks, thereby preserving the device’s compactness and circumventing a potential increase in the Z-height form factor. The suitability of the fin design for existing mold tooling implies seamless adaptability within current production workflows, avoiding the need for substantial capital outlays in new equipment. Employing a heat transfer layer that possesses a CTE that is compatible with the semiconductor die reduces a risk of thermal-induced stress, which tends to undermine the semiconductor device's reliability and structural integrity. Therefore, by optimizing thermal management in high-density electronic devices, this technology may ensure sustained operational performance with a prolonged device lifespan. In this way, quality and/or reliability of the semiconductor device is improved. By improving the quality and/or the reliability of the semiconductor device, an amount of resources used to support a market consuming the semiconductor device (e.g., raw materials, semiconductor manufacturing tools, labor, and/or computing resources) may be reduced.

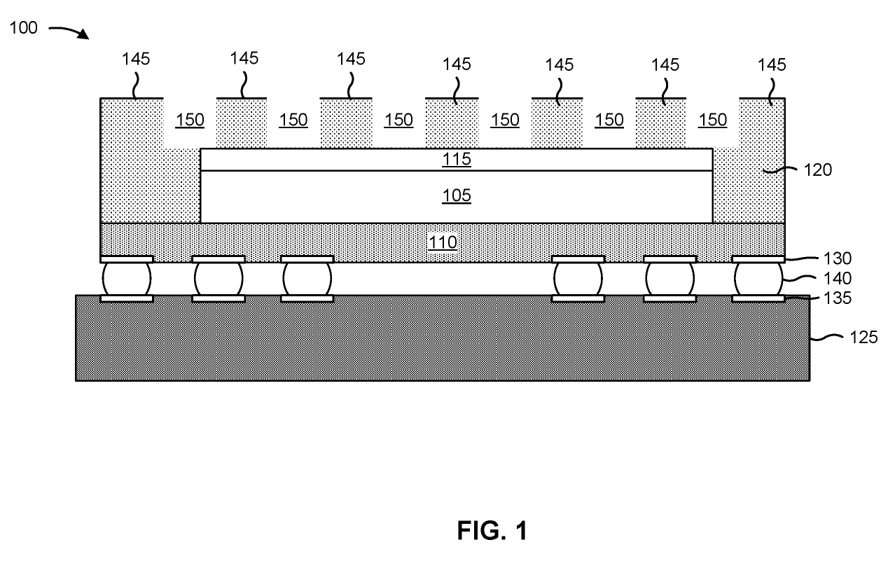

FIG. 1 is a diagram of an example apparatus 100 that may be manufactured using techniques described herein. The apparatus 100 may include any type of device or system that includes one or more semiconductor dies 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include an integrated circuit, such a semiconductor die 105 (sometimes called a die or a chip), disposed on a circuit substrate 110. The circuit substrate 110 may be a printed circuit board (PCB) or another type of chip carrier. The semiconductor die 105 may include any type of circuit, such as an analog circuit, a digital circuit, a controller (e.g., a microcontroller), a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). The semiconductor die 105 may be mounted on or otherwise disposed on a surface of the circuit substrate 110. Although the apparatus 100 is shown as including one semiconductor die 105 as an example, the apparatus 100 may include a different number of semiconductor dies 105, such as two or more semiconductor dies.

In some implementations, an integrated circuit may include a single semiconductor die 105, as shown in FIG. 1. In some implementations, an integrated circuit may include multiple semiconductor dies 105 (sometimes called dies) arranged in vertical stack that forms a die stack.

In some implementations, the apparatus 100 may include multiple integrated circuits, such as multiple laterally-separated semiconductor dies or multiple laterally-separated die stacks.

As shown in FIG. 1, the semiconductor die 105 may have a first die surface that faces away from the circuit substrate 110, and a second die surface that faces toward the circuit substrate 110. The apparatus 100 may include a heat transfer layer 115 (e.g., a convection heat transfer layer) arranged on a first die surface (e.g., an upper surface) of the semiconductor die 105. The heat transfer layer 115 may be configured to transfer heat generated by the semiconductor die 105 away from the semiconductor die 105. In some implementations, the heat transfer layer 115 is a dummy silicon layer. For example, the heat transfer layer 115 may be a bare (pure) silicon layer that contains no circuitry or modifications made by dopants. Additionally, the heat transfer layer 115 may have a CTE that is substantially matched (e.g., within 5%) to a semiconductor material of the semiconductor die 105. As a result of the substantially matched CTE, the semiconductor die 105 and the heat transfer layer 115 may undergo similar or proportional dimensional changes (e.g., thermal expansion and contraction) due to thermal changes. The substantially matched CTE may prevent the heat transfer layer 115 from inducing mechanical stress onto the semiconductor die 105, or vice versa, which may prevent warpage or other defects from occurring due to thermal expansion and contraction.

The apparatus 100 may include a package casing 120 that protects internal components of the apparatus 100 (e.g., the semiconductor die 105 and the heat transfer layer 115) from damage and environmental elements (e.g., particles) that can lead to malfunction of the apparatus 100. The package casing 120 and the heat transfer layer 115, together, may fully encapsulate the semiconductor die 105 to provide optimal protection to the semiconductor die 105. The package casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a PCB. For example, the circuit substrate 110 may be disposed on the circuit board 125 such that electrical contacts 130 (e.g., bond pads) of the circuit substrate 110 are electrically connected to electrical contacts 135 (e.g., bond pads) of the circuit board 125.

In some implementations, the circuit substrate 110 may be mounted on the circuit board 125 using solder balls 140 (e.g., arranged in a ball grid array), which may be melted to form a physical and electrical connection between the circuit substrate 110 and the circuit board 125. Additionally, or alternatively, the circuit substrate 110 may be mounted on and/or electrically connected to the circuit board 125 using another type of conductive connector, such as pins or leads. Similarly, the semiconductor die 105 may include electrical pads (e.g., bond pads) that are electrically connected to corresponding electrical pads (e.g., bond pads) of the circuit substrate 110 using electrical bonding, such as wire bonding, bump bonding, or the like. The interconnections between the semiconductor die 105, the circuit substrate 110, and the circuit board 125 enable the semiconductor die 105 to receive and transmit signals to other components of the apparatus 100 and/or the higher level system.

The package casing 120 may be arranged over the circuit substrate 110 to partially encapsulate the semiconductor die 105 and the heat transfer layer 115. Additionally, the package casing 120 may include a plurality of fin structures 145 and a plurality of channels 150 arranged over the heat transfer layer 115. The plurality of channels 150 may be defined by the plurality of fin structures 145. For example, the plurality of channels 150 may be recesses or trenches formed in the package casing 120, where each channel 150 is arranged between two respective fin structures 145. Thus, the plurality of fin structures 145 and the plurality of channels 150 may have an alternating arrangement whereby individual channels 150 alternate with individual fin structures 145.

The plurality of channels 150 may extend from an ambient environment into the package casing 120 to the heat transfer layer 115 to expose portions of the heat transfer layer 115 to the ambient environment. In other words, the heat transfer layer 115 may have exposed portions that are in contact with the ambient environment. The plurality of channels 15 may be configured to receive, from the heat transfer layer 115, the heat generated by the semiconductor die 105, and dissipate the heat into the ambient environment, away from the heat transfer layer 115 and the package casing 120 (e.g., away from the semiconductor die 105).

In some implementations, the heat transfer layer 115 may be configured to transfer the heat generated by the semiconductor die 105 to the plurality of channels 150 by convection heat transfer. For example, the plurality of channels 150 may be air flow channels or air convection trenches configured to receive convection air currents for removing the heat from the heat transfer layer 115 and the package casing 120 by convection heat transfer. In some implementations, the package casing 120 may be made out of a material that has a thermal conductivity coefficient (e.g., a K coefficient) of at least 3 watts per meter Kelvin (W/mK) (e.g., K ≥ 3). As a result, the package casing 120 may have sufficient thermal conductivity to aid in the thermal management of the semiconductor die 105. For example, the package casing 120 may assist in transferring the heat generated by the semiconductor die 105 to the heat transfer layer 115 and/or the plurality of channels 150.

In some implementations, the plurality of fin structures 145 and the plurality of channels 150 may extend laterally across a top of the package casing 120 in a first lateral direction, where the top of the package casing 120 is arranged opposite to the circuit substrate 110. Each channel 150 may extend from a first lateral side of the package casing to a second lateral side of the package casing, the second lateral side being arranged opposite to the first lateral side. Similarly, each fin structure 145 may be a strip of molding compound that extends from the first lateral side of the package casing to the second lateral side of the package casing. Thus, the plurality of fin structures 145 and the plurality of channels 150 may across a full lateral dimension of the package casing 120. The alternating arrangement of the plurality of fin structures 145 and the plurality of channels 150 may extend in a second lateral direction that is perpendicular to the first lateral direction

The combined thermal capabilities of the high K molding compound of the package casing 120, the heat transfer layer 115, and the plurality of channels 150 may quickly remove heat from the semiconductor die 105, leading to enhanced thermal management and improved operability of the semiconductor die 105. Moreover, the heat transfer layer 115 may be CTE compatible with the package casing 120 and the semiconductor die 105 to maintain structural integrity of the apparatus 100 throughout various temperature changes. Moreover, the plurality of channels 150 may eliminate a need for a separate heat sick that tends to increase a form height of semiconductor package assemblies. Moreover, the plurality of channels 150 may enable the heat transfer layer 115 to have larger thicknesses to improved thermal management.

As indicated above, FIG. 1 is provided as an example. Other examples may differ from what is described with regard to FIG. 1.

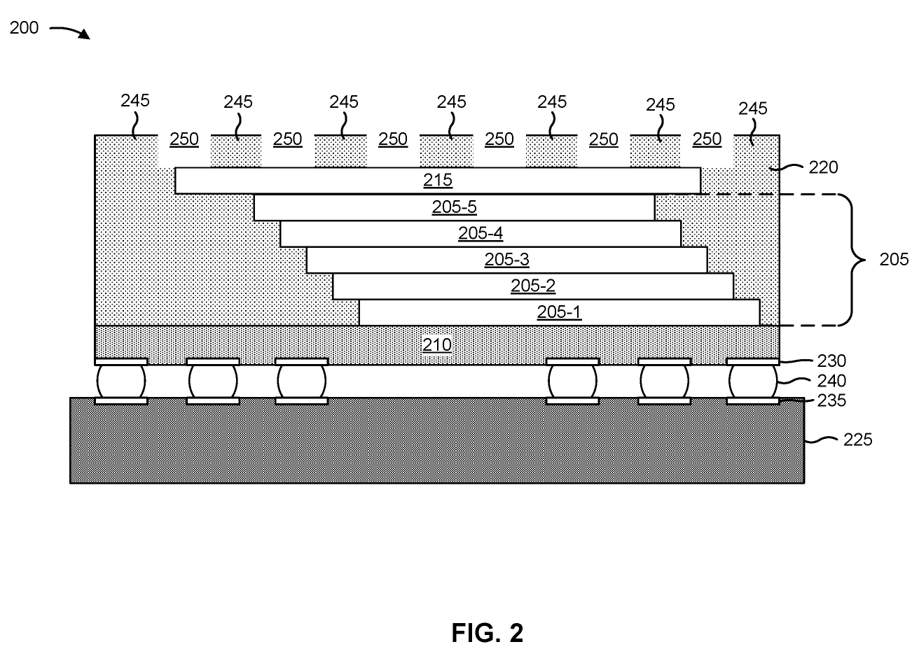

FIG. 2 is a diagram of an example apparatus 200 that may be manufactured using techniques described herein. The apparatus 200 may be similar to apparatus 100 described in connection with FIG. 1, except an integrated circuit 205 may be formed by a plurality of semiconductor dies 205-1, 205-2, 205-3, 205-4, and 205-5 arranged vertically in a die stack. Thus, the plurality of semiconductor dies may be stacked on top of each other to reduce a footprint of the apparatus 200.

In some implementations, a spacer may be present between dies 205-1, 205-2, 205-3, 205-4, and 205-5 that are adjacent to one another in the stack to enable electrical separation and heat dissipation. The stacked semiconductor dies 205-1, 205-2, 205-3, 205-4, and 205-5 may include three-dimensional electrical interconnects, such as through-silicon vias (TSVs), to route electrical signals between the semiconductor dies 205-1, 205-2, 205-3, 205-4, and 205-5. Although the integrated circuit 205 is shown as including five semiconductor dies, the integrated circuit 205 may include a different number of semiconductor dies (e.g., at least two semiconductor dies). A first semiconductor die 205-1 (sometimes called a bottom die or a base die) may be disposed on a circuit substrate 210 (e.g., proximate to the circuit substrate 210), a second semiconductor die 205-2 may be disposed on the first semiconductor die 205-1, and so on. The uppermost die (e.g., semiconductor die 205-5), furthest from the circuit substrate 210, may be referred to as a top semiconductor die or an upper semiconductor die.

The semiconductor dies 205-1, 205-2, 205-3, 205-4, and 205-5 may be arranged and connected in a shingle-stack configuration to form a shingle stack. In the shingle-stack configuration, die edges of the semiconductor dies 205-1, 205-2, 205-3, 205-4, and 205-5 are not aligned, but are instead offset from each other. Thus, each subsequent die of the die stack is offset from a previous die (e.g., a lower die) of the die stack. The shingle-stack configuration, with die edges that are offset, may provide space for wire bonding near the edges of the semiconductor dies 205-1, 205-2, 205-3, 205-4, and 205-5. Although FIG. 2 shows the semiconductor dies 205-1, 205-2, 205-3, 205-4, and 205-5 stacked in a shingle stack (e.g., with die edges that are not aligned), in some implementations, the semiconductor dies 205-1, 205-2, 205-3, 205-4, and 205-5 may be stacked in a different arrangement, such as a straight stack (e.g., with aligned die edges).

As shown in FIG. 2, the apparatus 200 may include a heat transfer layer 215 arranged on an upper surface of the upper semiconductor die (e.g., semiconductor die 205-5). The heat transfer layer 215 may be configured to transfer heat generated by the integrated circuit 205 (e.g., the die stack) away from the integrated circuit 205. In some implementations, the heat transfer layer 215 is a dummy silicon layer. For example, the heat transfer layer 215 may be a bare silicon layer that contains no circuitry or modifications made by dopants. Additionally, the heat transfer layer 215 may have a CTE that is substantially matched to a semiconductor material of the semiconductor dies 205-1, 205-2, 205-3, 205-4, and 205-5. As a result of the substantially matched CTE, the semiconductor dies 205-1, 205-2, 205-3, 205-4, and 205-5 and the heat transfer layer 215 may undergo similar or proportional dimensional changes (e.g., thermal expansion and contraction) due to thermal changes. The substantially matched CTE may prevent the heat transfer layer 215 from inducing mechanical stress onto the integrated circuit 205, or vice versa, which may prevent warpage or other defects from occurring due to thermal expansion and contraction.

The apparatus 200 may include a package casing 220 that protects internal components of the apparatus 200 (e.g., the integrated circuit 205 and the heat transfer layer 215) from damage and environmental elements (e.g., particles) that can lead to malfunction of the apparatus 200. The package casing 220 and the heat transfer layer 215, together, may fully encapsulate the integrated circuit 205 to provide optimal protection to the integrated circuit 205. The package casing 220 may be a mold compound, a plastic (e.g., an epoxy plastic), a ceramic, or another type of material depending on the functional requirements for the apparatus 200. For example, the package casing 220 may be similar to the package casing 120 described in connection with FIG. 1.

In some implementations, the apparatus 200 may be included as part of a higher level system (e.g., a computer, a mobile phone, a network device, an SSD, a vehicle, or an Internet of Things device), such as by electrically connecting the apparatus 200 to a circuit board 225, such as a PCB. For example, the circuit substrate 210 may be disposed on the circuit board 225 such that electrical contacts 230 (e.g., bond pads) of the circuit substrate 210 are electrically connected to electrical contacts 235 (e.g., bond pads) of the circuit board 225.

In some implementations, the circuit substrate 210 may be mounted on the circuit board 225 using solder balls 240 (e.g., arranged in a ball grid array), which may be melted to form a physical and electrical connection between the circuit substrate 210 and the circuit board 225. Additionally, or alternatively, the circuit substrate 210 may be mounted on and/or electrically connected to the circuit board 225 using another type of conductive connector, such as pins or leads. Similarly, the integrated circuit 205 may include electrical pads (e.g., bond pads) that are electrically connected to corresponding electrical pads (e.g., bond pads) of the circuit substrate 210 using electrical bonding, such as wire bonding, bump bonding, or the like. The interconnections between the integrated circuit 205, the circuit substrate 210, and the circuit board 225 enable the integrated circuit 205 to receive and transmit signals to other components of the apparatus 200 and/or the higher level system.

The package casing 220 may be arranged over the circuit substrate 210 to partially encapsulate the integrated circuit 205 (e.g., the die stack) and the heat transfer layer 215. Additionally, the package casing 220 may include a plurality of fin structures 245 and a plurality of channels 250 arranged over the heat transfer layer 215, as similarly described above in connection with FIG. 1. In other words, the plurality of fin structures 245 and a plurality of channels 250 may be similar to the plurality of fin structures 145 and the plurality of channels 150, respectively, both in structure and in function. Thus, the plurality of channels 250 may receive, from the heat transfer layer 215, the heat generated by the integrated circuit 205 and dissipate the heat into the ambient environment, away from the heat transfer layer 215 and the package casing 220 (e.g., away from the integrated circuit 205). The package casing 220 may be made out of a material that has a thermal conductivity coefficient of at least 3 W/mK, for similar reasons described above.

As indicated above, FIG. 2 is provided as an example. Other examples may differ from what is described with regard to FIG. 2.

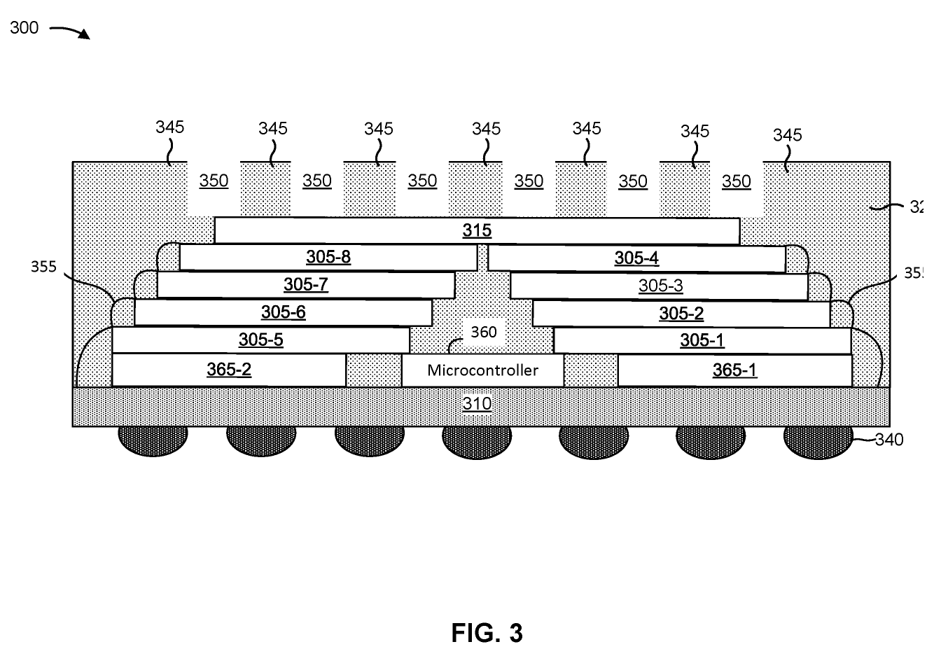

FIG. 3 is a diagram of an example apparatus 300 that may be manufactured using techniques described herein. The apparatus 300 may be similar to apparatus 200 described in connection with FIG. 2. However, the apparatus 300 may include multiple integrated circuits in the form of multiple die stacks. For example, a first integrated circuit may be formed by a first plurality of semiconductor dies 305-1, 305-2, 305-3, and 305-4 arranged vertically in a first die stack. A second integrated circuit may be formed by a second plurality of semiconductor dies 305-5, 305-6, 305-7, and 305-8 arranged vertically in a second die stack. The first die stack and the second die stack may have a similar configuration as the integrated circuit 205 described in connection with FIG. 2.

A first semiconductor die 305-1 (e.g., a bottom die or a base die) of the first die stack may be disposed on a circuit substrate 310 (e.g., proximate to the circuit substrate 310), a second semiconductor die 305-2 may be disposed on the first semiconductor die 305-1, and so on. The uppermost die (e.g., semiconductor die 305-4) of the first die stack, furthest from the circuit substrate 310, may be referred to as a first top semiconductor die or a first upper semiconductor die.

A fifth semiconductor die 305-5 (e.g., a bottom die or a base die) of the second die stack may be disposed on the circuit substrate 310 (e.g., proximate to the circuit substrate 310), a sixth semiconductor die 305-6 may be disposed on the fifth semiconductor die 305-5, and so on. The uppermost die (e.g., semiconductor die 305-8) of the second die stack, furthest from the circuit substrate 310, may be referred to as a second top semiconductor die or a second upper semiconductor die.

As shown in FIG. 3, the apparatus 300 may include a heat transfer layer 315 arranged on the first upper semiconductor die (e.g., semiconductor die 305-4) and on the second upper semiconductor die (e.g., semiconductor die 305-8). Thus, the heat transfer layer 315 spans across and overlays both upper semiconductor dies of the two die stacks. The heat transfer layer 315 may be configured to transfer heat generated by the first die stack and the second die stack away from the first die stack and the second die stack. Thus, the heat transfer layer 315 is thermally coupled to both die stacks. In some implementations, the heat transfer layer 315 is a dummy silicon layer. For example, the heat transfer layer 315 may be a bare silicon layer that contains no circuitry or modifications made by dopants. Additionally, the heat transfer layer 315 may have a CTE that is substantially matched to a semiconductor material of the semiconductor dies of the first die stack and the second die stack. As a result of the substantially matched CTE, the semiconductor dies of the first die stack and the second die stack and the heat transfer layer 315 may undergo similar or proportional dimensional changes (e.g., thermal expansion and contraction) due to thermal changes. The substantially matched CTE may prevent the heat transfer layer 315 from inducing mechanical stress onto the first die stack and the second die stack, or vice versa, which may prevent warpage or other defects from occurring due to thermal expansion and contraction.

The apparatus 300 may include a package casing 320 that protects internal components of the apparatus 300 (e.g., the integrated circuits and the heat transfer layer 315) from damage and environmental elements (e.g., particles) that can lead to malfunction of the apparatus 300. The package casing 320 and the heat transfer layer 315, together, may fully encapsulate the integrated circuits to provide optimal protection to the integrated circuits. The package casing 320 may be a mold compound, a plastic (e.g., an epoxy plastic), a ceramic, or another type of material depending on the functional requirements for the apparatus 300. For example, the package casing 320 may be similar to the package casing 120 described in connection with FIG. 1.

In some implementations, the apparatus 300 may be included as part of a higher-level system (e.g., a computer, a mobile phone, a network device, an SSD, a vehicle, or an Internet of Things device), such as by electrically connecting the apparatus 300 to a circuit board via solder balls 340 or another type of conductive connector. The solder balls 340 may be coupled to electrical contacts arranged at a bottom surface of the circuit substrate 310.

The package casing 320 may be arranged over the circuit substrate 310 to partially encapsulate the first die stack, the second die stack, and the heat transfer layer 315. Additionally, the package casing 320 may include a plurality of fin structures 345 and a plurality of channels 350 arranged over the heat transfer layer 315, as similarly described above in connection with FIGS. 1 and 2. In other words, the plurality of fin structures 345 and a plurality of channels 350 may be similar to the plurality of fin structures 145 and the plurality of channels 150, respectively, both in structure and in function. Thus, the plurality of channels 350 may receive, from the heat transfer layer 315, the heat generated by the first die stack and the second die stack, and dissipate the heat into the ambient environment, away from the heat transfer layer 315 and the package casing 320 (e.g., away from the first die stack and the second die stack). The package casing 320 may be made out of a material that has a thermal conductivity coefficient of at least 3 W/mK, for similar reasons described above.

In some implementations, bond wires 355 may be attached to lateral ends of the semiconductor dies 305. The lateral ends may be exposed for wire bonding due to a shingle-stack configuration of the die stacks. The bond wires 355 may be attached to the circuit substrate 310 form making an electrical connection between the semiconductor dies 305 and the circuit substrate 310 (e.g., to conductive traces and/or vias of the circuit substrate 310).

In some implementations, a microcontroller 360 may be arranged on, and electrically coupled to, the circuit substrate 310. The microcontroller 360 may be arranged laterally between the first die stack and the second die stack. The microcontroller 360 may be electrically coupled to the semiconductor dies 305 of the first die stack and the second die stack by conductive traces provided on and/or in the circuit substrate 310. The microcontroller 360 may control one or more data operations and/or memory operations of the semiconductor dies 305. The package casing 320, with a high K coefficient, may thermally couple the microcontroller 360 to the heat transfer layer 315. Thus, the plurality of channels 350 may receive, from the heat transfer layer 315, heat generated by the microcontroller 360, and dissipate the heat into the ambient environment, away from the heat transfer layer 315 and the package casing 320 (e.g., away from the microcontroller 360).

In some implementations, the first die stack may be arranged on a first spacer 365-1, and the second die stack may be arranged on a second spacer 365-2. The first spacer 365-1 and the second spacer 365-2 may enable the first die stack and the second die stack to vertically overlap with the microcontroller 360 to reduce a footprint of the apparatus 300.

As indicated above, FIG. 3 is provided as an example. Other examples may differ from what is described with regard to FIG. 3.

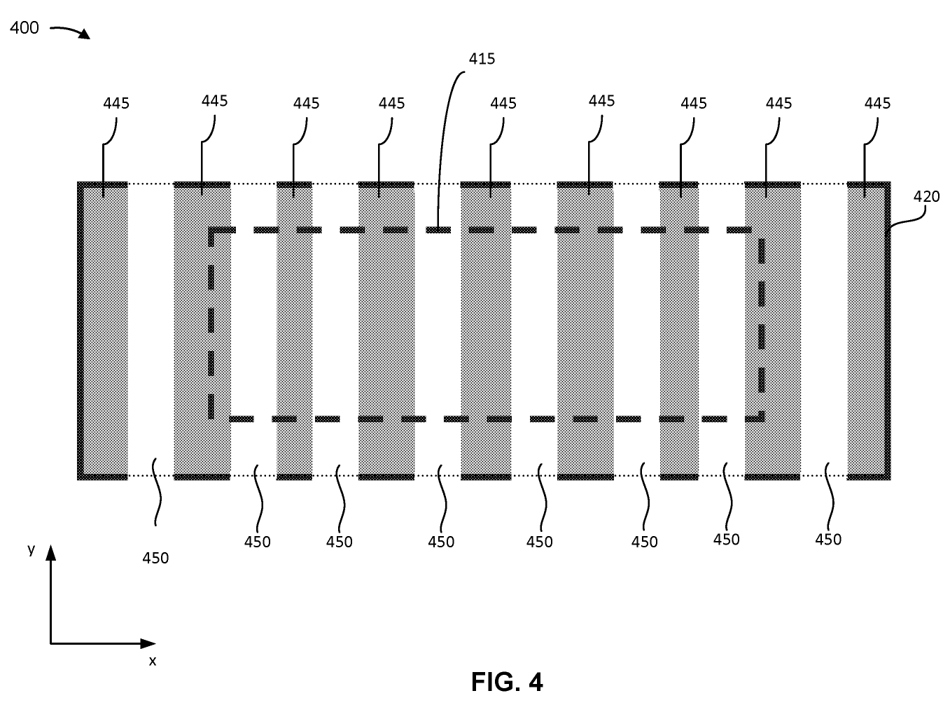

FIG. 4 shows a top view of an example apparatus 400. The example apparatus 400 may be apparatus 100, apparatus 200, or apparatus 300. The apparatus 400 may include a plurality of a plurality of fin structures 445 and a plurality of channels 450 arranged over a heat transfer layer 415, as similarly described above.

Thus, each channel 450 may extend from a first lateral side of a package casing 420 to a second lateral side of the package casing 420, the second lateral side being arranged opposite to the first lateral side. Additionally, each fin structure 445 may be a strip of molding compound that extends from the first lateral side of the package casing 420 to the second lateral side of the package casing 420. Thus, the plurality of fin structures 445 and the plurality of channels 450 may extend laterally across a top of the package casing 420 in a first lateral direction (e.g., along an x-axis). The plurality of fin structures 445 and the plurality of channels 450 may have an alternating arrangement that extends in a second lateral direction (e.g., along a y-axis) that is perpendicular to the first lateral direction. The heat transfer layer 415 and the package casing 420 may be configured to transfer heat to the plurality of channels 450 by convection heat transfer.

As indicated above, FIG. 4 is provided as an example. Other examples may differ from what is described with regard to FIG. 4.

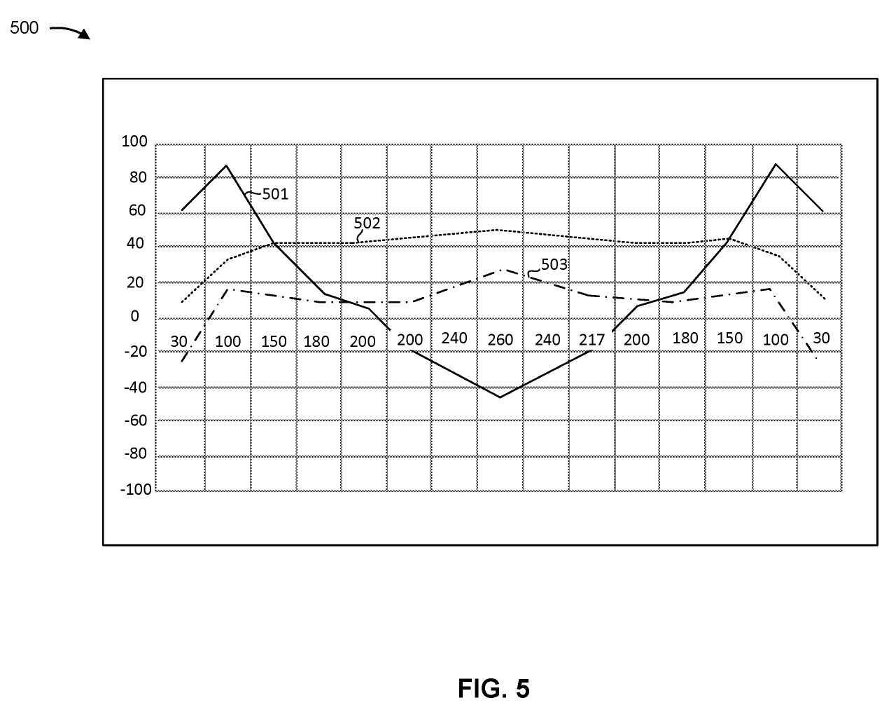

FIG. 5 is a graph 500 that depicts warpage profiles for different semiconductor device assemblies. The warpage profiles may represent an amount of warpage (y-axis) over temperature (x-axis). A first warpage profile 501 may correspond to a semiconductor device assembly that does not include a heat transfer layer, fin structures, or channels. A second warpage profile 502 may correspond to a semiconductor device assembly that includes a heat transfer layer, but does not include fin structures or channels. A third warpage profile 503 may correspond to a semiconductor device assembly that includes a heat transfer layer, fin structures, and channels. The third warpage profile 503 of the semiconductor device assembly that includes a heat transfer layer, fin structures, and channels is better than the first warpage profile 501 and the second warpage profile 502. For example, extreme amplitudes of warpage are less in the third warpage profile 503 than the extreme amplitudes of warpage in the first warpage profile 501 and the second warpage profile 502. Accordingly, the semiconductor device assembly that includes a heat transfer layer, fin structures, and channels may experience less warpage over wide range or temperatures compared to the other semiconductor device assemblies, which may lead to improved structural integrity and longer device lifetimes.

As indicated above, FIG. 5 is provided as an example. Other examples may differ from what is described with regard to FIG. 5.

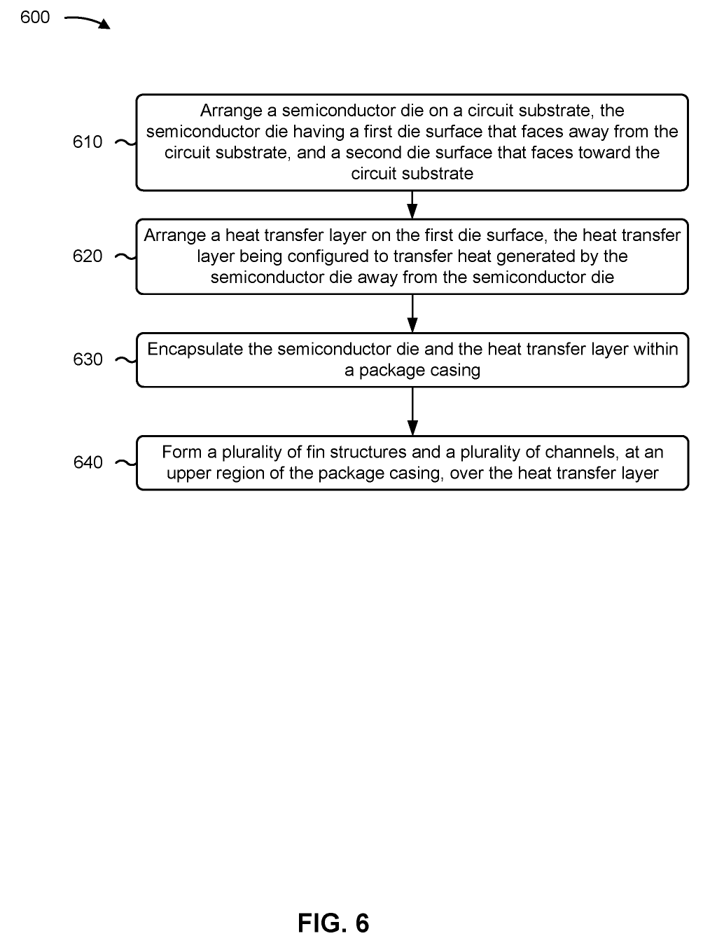

FIG. 6 is a flowchart of an example method 600 of forming an apparatus (e.g., a semiconductor device assembly) having a fin design molding structure for an exposed semiconductor package for convection heat transfer. The method 600 may be used to form apparatus 100, apparatus 200, and/or apparatus 300. In some implementations, one or more process blocks of FIG. 6 may be performed by various semiconductor manufacturing equipment.

As shown in FIG. 6, the method 600 may include arranging a semiconductor die on a circuit substrate, the semiconductor die having a first die surface that faces away from the circuit substrate, and a second die surface that faces toward the circuit substrate (block 610). As further shown in FIG. 6, the method 600 may include arranging a heat transfer layer on the first die surface, wherein the heat transfer layer is configured to transfer heat generated by the semiconductor die away from the semiconductor die (block 620). As further shown in FIG. 6, the method 600 may include encapsulating the semiconductor die and the heat transfer layer within a package casing (block 630). As further shown in FIG. 6, the method 600 may include forming a plurality of fin structures and a plurality of channels, at an upper region of the package casing, over the heat transfer layer (block 640). The plurality of channels may be defined by the plurality of fin structures. The plurality of channels may extend from an ambient environment into the package casing to the heat transfer layer to expose portions of the heat transfer layer to the ambient environment. The plurality of channels may receive, from the heat transfer layer, the heat generated by the semiconductor die, and dissipate the heat into the ambient environment, away from the heat transfer layer and the package casing.

The method 600 may include additional aspects, such as any single aspect or any combination of aspects described below and/or in connection with one or more other methods described elsewhere herein.

In a first aspect, the plurality of channels may be air flow channels configured to receive convection air currents for removing the heat from the heat transfer layer and the package casing by convection heat transfer.

In a second aspect, alone or in combination with the first aspect, the heat transfer layer may have a CTE that is substantially matched to a semiconductor material of the semiconductor die. Additionally, the package casing may be made out of a material that has a thermal conductivity coefficient of at least 3 W/mK.

Although FIG. 6 shows example blocks of the method 600, in some implementations, the method 600 may include additional blocks, fewer blocks, different blocks, or differently arranged blocks than those depicted in FIG. 6.

In some implementations, a semiconductor device assembly includes a circuit substrate; a semiconductor die arranged on, and electrically coupled to, the circuit substrate, the semiconductor die having a first die surface that faces away from the circuit substrate, and a second die surface that faces toward the circuit substrate; a heat transfer layer arranged on the first die surface, wherein the heat transfer layer is configured to transfer heat generated by the semiconductor die away from the semiconductor die; and a package casing arranged over the circuit substrate to partially encapsulate the semiconductor die and the heat transfer layer, wherein the package casing includes a plurality of fin structures and a plurality of channels arranged over the heat transfer layer, wherein the plurality of channels are defined by the plurality of fin structures, wherein the plurality of channels extend from an ambient environment into the package casing to the heat transfer layer to expose portions of the heat transfer layer to the ambient environment, and wherein the plurality of channels are configured to receive, from the heat transfer layer, the heat generated by the semiconductor die, and dissipate the heat into the ambient environment, away from the heat transfer layer and the package casing.

In some implementations, a semiconductor device assembly includes a circuit substrate; a first die stack arranged on, and electrically coupled to, the circuit substrate, the first die stack comprising a first plurality of semiconductor dies that include a first bottom semiconductor die arranged proximate to the circuit substrate and a first upper semiconductor die arranged away from the circuit substrate; a second die stack arranged on, and electrically coupled to, the circuit substrate, the second die stack comprising a second plurality of semiconductor dies that include a second bottom semiconductor die arranged proximate to the circuit substrate and a second upper semiconductor die arranged away from the circuit substrate; a heat transfer layer arranged on the first upper semiconductor die and the second upper semiconductor die, wherein the heat transfer layer is configured to transfer heat generated by the first die stack and the second die stack away from the first die stack and the second die stack; and a package casing arranged over the circuit substrate to partially encapsulate the first die stack, the second die stack, and the heat transfer layer, wherein the package casing includes a plurality of fin structures and a plurality of channels arranged over the heat transfer layer, wherein the plurality of channels are defined by the plurality of fin structures, wherein the plurality of channels extend from an ambient environment into the package casing to the heat transfer layer to expose portions of the heat transfer layer to the ambient environment, and wherein the plurality of channels are configured to receive, from the heat transfer layer, the heat generated by the first die stack and the second die stack, and dissipate the heat into the ambient environment, away from the heat transfer layer and the package casing.

In some implementations, a method of manufacturing a semiconductor device assembly includes arranging a semiconductor die on a circuit substrate, the semiconductor die having a first die surface that faces away from the circuit substrate, and a second die surface that faces toward the circuit substrate; arranging a heat transfer layer on the first die surface, wherein the heat transfer layer is configured to transfer heat generated by the semiconductor die away from the semiconductor die; encapsulating the semiconductor die and the heat transfer layer within a package casing; and forming a plurality of fin structures and a plurality of channels, at an upper region of the package casing, over the heat transfer layer, wherein the plurality of channels are defined by the plurality of fin structures, wherein the plurality of channels extend from an ambient environment into the package casing to the heat transfer layer to expose portions of the heat transfer layer to the ambient environment, and wherein the plurality of channels are configured to receive, from the heat transfer layer, the heat generated by the semiconductor die, and dissipate the heat into the ambient environment, away from the heat transfer layer and the package casing.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element’s relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a circuit substrate;
a semiconductor die arranged on, and electrically coupled to, the circuit substrate, the semiconductor die having a first die surface that faces away from the circuit substrate, and a second die surface that faces toward the circuit substrate;
a heat transfer layer arranged on the first die surface, wherein the heat transfer layer is configured to transfer heat generated by the semiconductor die away from the semiconductor die; and
a package casing arranged over the circuit substrate to partially encapsulate the semiconductor die and the heat transfer layer,
wherein the package casing includes a plurality of fin structures and a plurality of channels arranged over the heat transfer layer,
wherein the plurality of channels are defined by the plurality of fin structures,
wherein the plurality of channels extend from an ambient environment into the package casing to the heat transfer layer to expose portions of the heat transfer layer to the ambient environment, and
wherein the plurality of channels are configured to receive, from the heat transfer layer, the heat generated by the semiconductor die, and dissipate the heat into the ambient environment, away from the heat transfer layer and the package casing.

2. The semiconductor device assembly of claim 1, wherein the heat transfer layer is configured to transfer the heat generated by the semiconductor die to the plurality of channels by convection heat transfer.

3. The semiconductor device assembly of claim 1, wherein the plurality of channels are air flow channels configured to receive convection air currents for removing the heat from the heat transfer layer and the package casing by convection heat transfer.

4. The semiconductor device assembly of claim 1, wherein each channel of the plurality of channels is arranged between two respective fin structures of the plurality of fin structures.

5. The semiconductor device assembly of claim 1, wherein the plurality of fin structures and the plurality of channels have an alternating arrangement whereby individual channels of the plurality of channels alternate with individual fin structures of the plurality of fin structures.

6. The semiconductor device assembly of claim 1, wherein the plurality of fin structures and the plurality of channels extend laterally across a top of the package casing in a first lateral direction, and
wherein the top of the package casing is arranged opposite to the circuit substrate.

7. The semiconductor device assembly of claim 6, wherein each channel of the plurality of channels extends from a first lateral side of the package casing to a second lateral side of the package casing, the second lateral side being arranged opposite to the first lateral side, and
wherein each fin structure of the plurality of fin structures is a strip of molding compound that extends from the first lateral side of the package casing to the second lateral side of the package casing.

8. The semiconductor device assembly of claim 6, wherein the plurality of fin structures and the plurality of channels have an alternating arrangement that extends in a second lateral direction that is perpendicular to the first lateral direction.

9. The semiconductor device assembly of claim 1, wherein the heat transfer layer is a dummy silicon layer.

10. The semiconductor device assembly of claim 1, wherein the heat transfer layer is a bare silicon layer.

11. The semiconductor device assembly of claim 1, wherein the heat transfer layer has a coefficient of thermal expansion that is substantially matched to a semiconductor material of the semiconductor die.

12. The semiconductor device assembly of claim 1, wherein the package casing and the heat transfer layer, together, fully encapsulate the semiconductor die.

13. The semiconductor device assembly of claim 1, wherein the package casing is made out of a material that has a thermal conductivity coefficient of at least 3 watts per meter Kelvin (W/mK).

14. A semiconductor device assembly, comprising:
a circuit substrate;
a first die stack arranged on, and electrically coupled to, the circuit substrate, the first die stack comprising a first plurality of semiconductor dies that include a first bottom semiconductor die arranged proximate to the circuit substrate and a first upper semiconductor die arranged away from the circuit substrate;
a second die stack arranged on, and electrically coupled to, the circuit substrate, the second die stack comprising a second plurality of semiconductor dies that include a second bottom semiconductor die arranged proximate to the circuit substrate and a second upper semiconductor die arranged away from the circuit substrate;
a heat transfer layer arranged on the first upper semiconductor die and the second upper semiconductor die, wherein the heat transfer layer is configured to transfer heat generated by the first die stack and the second die stack away from the first die stack and the second die stack; and
a package casing arranged over the circuit substrate to partially encapsulate the first die stack, the second die stack, and the heat transfer layer,
wherein the package casing includes a plurality of fin structures and a plurality of channels arranged over the heat transfer layer,
wherein the plurality of channels are defined by the plurality of fin structures,
wherein the plurality of channels extend from an ambient environment into the package casing to the heat transfer layer to expose portions of the heat transfer layer to the ambient environment, and
wherein the plurality of channels are configured to receive, from the heat transfer layer, the heat generated by the first die stack and the second die stack, and dissipate the heat into the ambient environment, away from the heat transfer layer and the package casing.

15. The semiconductor device assembly of claim 14, wherein the heat transfer layer is configured to transfer the heat generated by the first die stack and the second die stack to the plurality of channels by convection heat transfer.

16. The semiconductor device assembly of claim 14, wherein the plurality of channels are air flow channels configured to receive convection air currents for removing the heat from the heat transfer layer and the package casing by convection heat transfer.

17. The semiconductor device assembly of claim 14, wherein the plurality of fin structures and the plurality of channels have an alternating arrangement whereby individual channels of the plurality of channels alternate with individual fin structures of the plurality of fin structures.

18. The semiconductor device assembly of claim 14, wherein the plurality of fin structures and the plurality of channels extend laterally across a top of the package casing in a first lateral direction, and
wherein the top of the package casing is arranged opposite to the circuit substrate.

19. The semiconductor device assembly of claim 18, wherein each channel of the plurality of channels extends from a first lateral side of the package casing to a second lateral side of the package casing, the second lateral side being arranged opposite to the first lateral side, and
wherein each fin structure of the plurality of fin structures is a strip of molding compound that extends from the first lateral side of the package casing to the second lateral side of the package casing.

20. The semiconductor device assembly of claim 14, wherein the heat transfer layer is a bare silicon layer.

21. The semiconductor device assembly of claim 14, wherein the heat transfer layer has a coefficient of thermal expansion that is substantially matched to a semiconductor material of the first die stack and the second die stack.

22. The semiconductor device assembly of claim 14, wherein the package casing is made out of a material that has a thermal conductivity coefficient of at least 3 watts per meter Kelvin (W/mK).

23. A method of manufacturing a semiconductor device assembly, the method comprising:
arranging a semiconductor die on a circuit substrate, the semiconductor die having a first die surface that faces away from the circuit substrate, and a second die surface that faces toward the circuit substrate;
arranging a heat transfer layer on the first die surface, wherein the heat transfer layer is configured to transfer heat generated by the semiconductor die away from the semiconductor die;
encapsulating the semiconductor die and the heat transfer layer within a package casing; and
forming a plurality of fin structures and a plurality of channels, at an upper region of the package casing, over the heat transfer layer,
wherein the plurality of channels are defined by the plurality of fin structures,
wherein the plurality of channels extend from an ambient environment into the package casing to the heat transfer layer to expose portions of the heat transfer layer to the ambient environment, and
wherein the plurality of channels are configured to receive, from the heat transfer layer, the heat generated by the semiconductor die, and dissipate the heat into the ambient environment, away from the heat transfer layer and the package casing.

24. The method of claim 23, wherein the plurality of channels are air flow channels configured to receive convection air currents for removing the heat from the heat transfer layer and the package casing by convection heat transfer.

25. The method of claim 23, wherein the heat transfer layer has a coefficient of thermal expansion that is substantially matched to a semiconductor material of the semiconductor die, and
wherein the package casing is made out of a material that has a thermal conductivity coefficient of at least 3 watts per meter Kelvin (W/mK).
